(19) United States
(12) Patent Application Publication
(10) Pub. No.: US 2025/0149435 A1
(43) Pub. Date: May 8, 2025

(54) SEMICONDUCTOR DEVICE

(71) Applicant: SUMITOMO ELECTRIC INDUSTRIES, LTD., Osaka (JP)

(72) Inventors: Sadanori ARAE, Osaka-shi (JP); Hayato SHIMIZU, Osaka-shi (JP)

(73) Assignee: SUMITOMO ELECTRIC INDUSTRIES, LTD., Osaka (JP)

(21) Appl. No.: 18/936,438

(22) Filed: Nov. 4, 2024

(30) Foreign Application Priority Data
Nov. 6, 2023 (JP) 2023-189225

(51) Int. Cl. H01L 23/522; H01L 23/528

(52) U.S. Cl. CPC H01L 23/5223; H01L 23/5226; H01L 23/5283

(57) ABSTRACT

A semiconductor device includes: a substrate; a first metal film provided above a main surface of the substrate; a first insulating layer provided on the first metal film; a second metal film provided on the first insulating layer; a plurality of first vias penetrating the first insulating layer to connect the first metal film with the second metal film; a second insulating layer provided on the second metal film; a third metal film provided on the second insulating layer and insulated from the second metal film by the second insulating layer; a fourth metal film provided on a back surface of the substrate; and a second via penetrating the substrate to connect the first metal film with the fourth metal film, and provided at a position overlapping the second metal film when viewed from the normal direction of the main surface.

### CROSS REFERENCE TO RELATED APPLICATIONS

Priority is claimed on Japanese Patent Application No. 2023-189225 filed on Nov. 6, 2023, the entire content of which is incorporated herein by reference.

### TECHNICAL FIELD

The present disclosure relates to a semiconductor device.

### BACKGROUND OF THE INVENTION

Japanese Unexamined Patent Publication No. 2003-283070 discloses a wiring board having a built-in capacitive element. This wiring board includes two capacitive element electrode layers. The outer periphery of one of the capacitive element electrode layers is located outside the outer periphery of the other capacitive element electrode layer. A frame-shaped auxiliary capacitive element electrode layer connected to one of the capacitive element electrode layers surrounds the other capacitive element electrode layer. The inner periphery of the auxiliary capacitive element electrode layer is located inside the outer periphery of one of the capacitive element electrode layers. Japanese Unexamined Patent Publication No. 2018-37497 discloses a semiconductor device. Japanese Unexamined Patent Publication No. 2004-193563 discloses a semiconductor device having an MIM capacitor. Japanese Unexamined Patent Publication No. 2004-6958 discloses an MIM capacitor and a high-frequency integrated circuit.

### SUMMARY OF THE INVENTION

A semiconductor device according to an aspect of the present disclosure includes: a substrate having a main surface and a back surface opposite to the main surface; a first metal film provided on the main surface of the substrate; a first insulating layer provided on the first metal film and in contact with the first metal film; a second metal film provided on the first insulating layer and in contact with the first insulating layer; a plurality of first vias penetrating the first insulating layer to connect the first metal film with the second metal film; a second insulating layer provided on the second metal film and in contact with the second metal film; a third metal film provided on the second insulating layer, in contact with the second insulating layer, and insulated from the second metal film by the second insulating layer; a fourth metal film provided on the back surface of the substrate; and a second via penetrating the substrate to connect the first metal film with the fourth metal film. The second metal film, the second insulating layer, and the third metal film form an MIM capacitor. The plurality of first vias, the first metal film, and the second via are aligned with the MIM capacitor in a normal direction of the main surface.

### BRIEF DESCRIPTION OF THE DRAWINGS

FIG. 1 is a plan view showing a semiconductor device according to an embodiment of the present disclosure.

FIG. 2 is a cross-sectional view of the semiconductor device taken along the line II-II shown in FIG. 1.

FIG. 3 shows, as an example, a case where the cross-sectional shape of each of a plurality of first vias is a polygon.

FIG. 4 is a cross-sectional view showing a semiconductor device according to a modification example.

FIG. 5 is a plan view showing a semiconductor device according to another modification example of the present disclosure.

FIG. 6 is a cross-sectional view of the semiconductor device taken along line VI-VI shown in FIG. 5.

### DETAILED DESCRIPTION

For example, in semiconductor devices such as a monolithic microwave integrated circuit (MMIC), a metal-insulator-metal (MIM) capacitor is often provided in a wiring layer. Since the capacitance of the MIM capacitor is proportional to the area, the area of the MIM capacitor increases with the capacitance of the MIM capacitor. On the other hand, in semiconductor devices such as an MMIC, miniaturization due to a reduction in the wiring area is required.

The present disclosure has been made in consideration of such a problem, and it is an object of the present disclosure to enable miniaturization by reducing the wiring area in a semiconductor device having an MIM capacitor.

### Embodiments of Present Disclosure

First, the contents of embodiments of the present disclosure will be listed and described.

A semiconductor device according to an aspect of the present disclosure includes: a substrate having a main surface and a back surface opposite to the main surface; a first metal film provided on the main surface of the substrate; a first insulating layer provided on the first metal film and in contact with the first metal film; a second metal film provided on the first insulating layer and in contact with the first insulating layer; a plurality of first vias penetrating the first insulating layer to connect the first metal film with the second metal film; a second insulating layer provided on the second metal film and in contact with the second metal film; a third metal film provided on the second insulating layer, in contact with the second insulating layer, and insulated from the second metal film by the second insulating layer; a fourth metal film provided on the back surface of the substrate; and a second via penetrating the substrate to connect the first metal film with the fourth metal film. The second metal film, the second insulating layer, and the third metal film form an MIM capacitor. The plurality of first vias, the first metal film, and the second via are aligned with the MIM capacitor in a normal direction of the main surface.

In the semiconductor device according to [1] above, the plurality of first vias, the first metal film, and the second vias are aligned with the MIM capacitor in a direction perpendicular to the main surface of the substrate (that is, in the thickness direction of the substrate). Therefore, it is possible to reduce the wiring area compared to a case where a lead-out wiring (for example, a ground wiring) from one electrode of the MIM capacitor is arranged in parallel with the MIM capacitor as in the structure described in Japanese Unexamined Patent Publication No. 2018-37497, for example. As a result, it is possible to reduce the size of a semiconductor device having an MIM capacitor.

[2] In the semiconductor device according to [1] above, the third metal film may be provided so as to avoid a region above each of the plurality of first vias. Each of the plurality of first vias is formed by forming a hole in the first insulating layer and filling the hole with a metal material. When filling the hole in the first insulating layer with a metal material, unevenness may occur on the top surface of the first via. In this case, the top surface of the second metal film formed on the first via and the top surface of the second insulating layer formed on the second metal film also inherit the unevenness. When the third metal film is formed on such unevenness, there is a risk that the breakdown voltage of the MIM capacitor may be reduced. By providing the third metal film so as to avoid the region directly above each of the plurality of first vias, a reduction in the breakdown voltage of the MIM capacitor can be avoided.

[3] In the semiconductor device according to [1] or [2] above, the substrate may be a silicon carbide substrate.

[4] In the semiconductor device according to [1] or [3] above, a cross-sectional shape of each of the plurality of first vias when each of the plurality of first vias is cut in a cross section along the main surface may be a polygon, and each of a plurality of corners of the polygon may be larger than 90°. When the cross-sectional shape of each of the plurality of first vias is a polygon, the smaller the angle of each of the plurality of corners of the polygon, the slower the deposition rate of the metal material at the plurality of corners when filling the hole in the first insulating layer with the metal material. Therefore, unevenness occurs on the top surface of the first via. Then, the unevenness of the top surface of the first via is noticeable when each of the plurality of corners of the polygon is 90° or less. Therefore, if each of the plurality of corners of the polygon is set to have an angle larger than 90°, the unevenness of the top surface of the first via can be kept small. As a result, a reduction in the breakdown voltage of the MIM capacitor can be avoided by keeping small the unevenness of the top surface of the second metal film formed on the first via and the unevenness of the top surface of the second insulating layer formed on the second metal film.

[5] In the semiconductor device according to [4] above, the polygon may be a regular polygon. In this case, when filling the hole in the first insulating layer with a metal material, the growth rate of the metal material can be made nearly uniform along the circumferential direction of the hole. Therefore, the unevenness of the top surface of the first via can be further reduced.

[6] In the semiconductor device according to [1] to [5] above, the plurality of first vias may contain at least one metal material selected from a group consisting of Au, Cu, W, Ti, Al, Ru, and Co. In this case, it becomes easy to deposit the material of the first via on the sidewall of the hole having a high aspect ratio by a CVD process or a plating process.

### Details of Embodiments of Present Disclosure

Specific examples of a semiconductor device of the present disclosure will be described below with reference to the accompanying drawings. The present invention is not limited to these examples, but is defined by the claims, and is intended to include all modifications within the meaning and scope equivalent to the claims. In the following description, the same elements will be denoted by the same reference numerals in the description of the drawings, and repeated description thereof will be omitted.

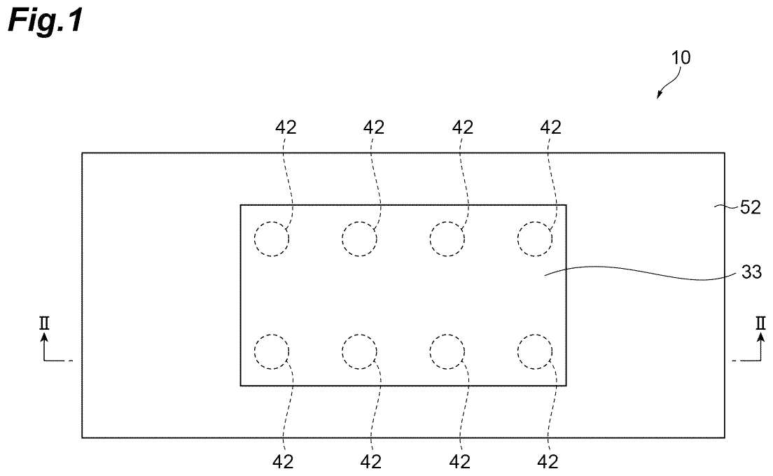

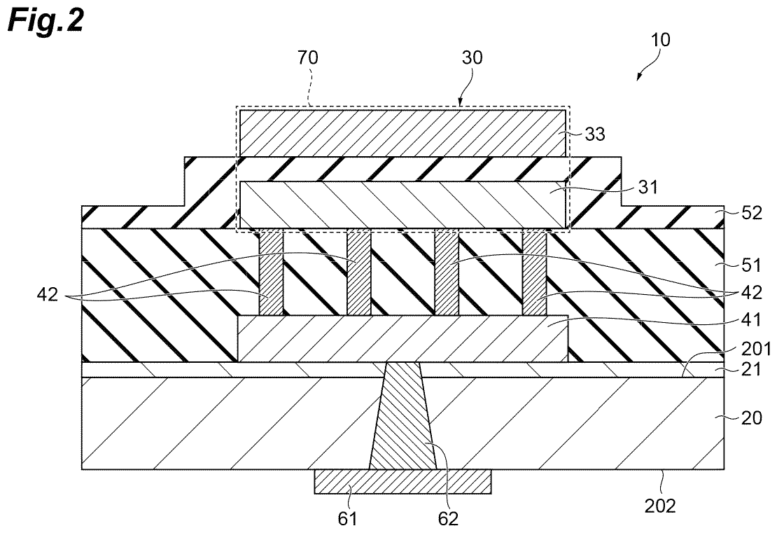

FIG. 1 is a plan view showing a semiconductor device 10 according to an embodiment of the present disclosure. FIG. 2 is a cross-sectional view of the semiconductor device 10 taken along the line II-II shown in FIG. 1. As shown in FIGS. 1 and 2, the semiconductor device 10 according to the present embodiment includes a substrate 20, a semiconductor layer 21, a first metal film 41, a plurality of first vias 42, a second metal film 31, a third metal film 33, a first insulating layer 51, a second insulating layer 52, a fourth metal film 61, and a second via 62.

The substrate 20 has a main surface 201 and a back surface 202 opposite to the main surface 201. Both the main surface 201 and the back surface 202 are flat and parallel to each other. The substrate 20 is an insulating substrate, such as a silicon carbide (SiC) substrate or a sapphire substrate.

The semiconductor layer 21 is a semiconductor layer provided on the main surface 201 of the substrate 20 by epitaxial growth. The semiconductor layer 21 contains, for example, a III-V compound semiconductor as its composition. In one example, the semiconductor layer 21 contains a GaN-based semiconductor as its composition. The semiconductor layer 21 may include a channel layer and a barrier layer for a high electron mobility transistor (HEMT). The channel layer and the barrier layer may be a GaN layer and an AlGaN layer, respectively. The combined thickness of the substrate 20 and the semiconductor layer 21 is, for example, 10 μm.

The first metal film 41 is a metal film provided on the main surface 201 of the substrate 20. In one example, the first metal film 41 is provided on the semiconductor layer 21 and is in contact with the semiconductor layer 21. The first metal film 41 is conductive. The first metal film 41 is formed by stacking a nickel (Ni) layer and a gold (Au) layer in this order, for example. The thickness of the first metal film 41 is, for example, 0.1 μm or more and 10 μm or less. The first metal film 41 has a planar shape, such as a rectangular shape, when viewed from the normal direction of the main surface 201 (hereinafter, also referred to as in plan view). Hereinafter, the planar shape refers to a shape in plan view. The length of the short side of the first metal film 41 is, for example, 1 μm or more and 1000 μm or less. The length of the long side of the first metal film 41 is, for example, 1 μm or more and 1000 μm or less. The planar shape of the first metal film 41 is not limited to the rectangular shape.

The first insulating layer 51 is an insulating layer provided on the first metal film 41 and above a region of the main surface 201 where the first metal film 41 is not provided. The first insulating layer 51 is in contact with all surfaces of the first metal film 41 other than the surface facing the main surface 201, that is, top and side surfaces of the first metal film 41 and a region of the main surface 201 where the first metal film 41 is not provided. In other words, the first insulating layer 51 covers the first metal film 41 above the main surface 201. The first insulating layer 51 is provided over the entire main surface 201. The first insulating layer 51 has an insulating property. The first insulating layer 51 is, for example, a silicon oxide (SiO) film, a silicon nitride (SiN) film, or a silicon oxynitride (SiON) film. The thickness of the first insulating layer 51 on the first metal film 41 is, for example, 0.2 μm or more and 10 μm or less.

The second metal film 31 is a metal film provided on the first insulating layer 51 and is in contact with the first insulating layer 51. The second metal film 31 includes a portion overlapping the first metal film 41 when viewed from the normal direction of the main surface 201 of the substrate 20. In the shown example, the entire second metal film 31 overlaps the first metal film 41 in plan view. The second metal film 31 is conductive. The second metal film 31 is formed by stacking a first titanium (Ti) layer, a gold (Au) layer, and a second titanium (Ti) layer in this order, for example. The thickness of the second metal film 31 is, for example, 0.1 μm or more and 10 μm or less. The second metal film 31 has a planar shape such as a rectangular shape. The range of the length of the short side and the range of the length of the long side of the second metal film 31 are the same as those of the first metal film 41 described above, for example. The planar shape of the second metal film 31 is also not limited to the rectangular shape.

The plurality of first vias 42 are arranged on the first metal film 41 side by side in a one-dimensional or two-dimensional manner in a plane along the main surface 201. The plane may be parallel to the main surface 201. In the shown example, the plurality of first vias 42 are aligned in two rows along the long side direction of the first metal film 41, but the arrangement of the plurality of first vias 42 is not limited thereto. The plurality of first vias 42 may be arbitrarily arranged at appropriate intervals therebetween in a plane along the main surface 201. The plane may be parallel to the main surface 201. The plurality of first vias 42 penetrate the first insulating layer 51 to connect the first metal film 41 with the second metal film 31. Each of the first vias 42 contains at least one metal material selected from a group consisting of, gold (Au), copper (Cu), tungsten (W), titanium (Ti), aluminum (Al), ruthenium (Ru), and cobalt (Co), for example. The second metal film 31 is electrically connected to the first metal film 41 by the plurality of first vias 42. If the plurality of first vias 42 are not provided, the second metal film 31 is insulated from the first metal film 41 by the first insulating layer 51. The number of the plurality of first vias 42 is at least two. By increasing the number of the plurality of first vias 42, the second metal film 31 can be electrically connected to the first metal film 41 more reliable. For example, the number of the plurality of first vias 42 may be four or more. For example, when an MIM capacitor 70 is used in a high-frequency circuit, the effect of the parasitic inductance of one first via 42 on the high-frequency circuit can be reduced by providing four or more first vias 42.

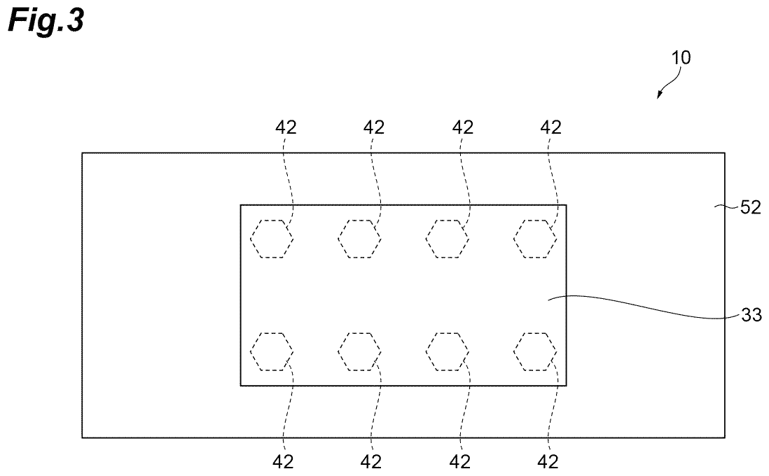

In the shown example, the cross-sectional shape of each first via 42 when each first via 42 is cut in a cross section along the main surface 201 is a circle. The cross section may be parallel to the main surface 201. The diameter of each first via 42 is, for example, 0.5 μm or more and 10 μm or less. Each first via 42 is not limited to having the circular shape, and may have various cross-sectional shapes. FIG. 3 shows, as an example, a case where the cross-sectional shape of each first via 42 is a polygon. Each of a plurality of corners of the polygon is larger than 90°. As shown in the example, the polygon may be a regular polygon, such as a regular hexagon or a regular octagon.

The second insulating layer 52 is an insulating layer provided on the second metal film 31 and on a region of the first insulating layer 51 where the second metal film 31 is not provided. The second insulating layer 52 is in contact with all surfaces of the second metal film 31 other than the surface in contact with the first insulating layer 51, that is, top and side surfaces of the second metal film 31 and a region of the first insulating layer 51 where the second metal film 31 is not provided. In other words, the second insulating layer 52 covers the second metal film 31 on the first insulating layer 51. The second insulating layer 52 is provided over the entire surface of the first insulating layer 51, that is, over the entire main surface 201. The second insulating layer 52 has an insulating property. The dielectric constant of the second insulating layer 52 is larger than the dielectric constant of the first insulating layer 51. The second insulating layer 52 is, for example, a silicon oxide (SiO) film, a silicon nitride (SiN) film, or a silicon oxynitride (SiON) film. The thickness of the second insulating layer 52 on the second metal film 31 is smaller than the thickness of the first insulating layer 51 on the first metal film 41, and is, for example, 0.01 μm or more and 0.5 μm or less.

The third metal film 33 is a metal film provided above the second metal film 31 and on the second insulating layer 52, and is in contact with the second insulating layer 52. The third metal film 33 includes a portion overlapping both the first metal film 41 and the second metal film 31 when viewed from the normal direction of the main surface 201. In the shown example, the entire third metal film 33 overlaps both the first metal film 41 and the second metal film 31. In the present embodiment, the third metal film 33 overlaps the plurality of first vias 42 when viewed from the normal direction of the main surface 201. The third metal film 33 is conductive. The third metal film 33 is insulated from the second metal film 31 by the second insulating layer 52. The second metal film 31, the second insulating layer 52, and the third metal film 33 form the MIM capacitor 70. That is, the MIM capacitor 70 is aligned with the first metal film 41 and the plurality of first vias 42 in the normal direction of the main surface 201. The MIM capacitor 70 may be used as a coupling capacitor or a filter capacitor in the semiconductor device 10. Similarly to the second metal film 31, the third metal film 33 is formed by stacking a first titanium (Ti) layer, a gold (Au) layer, and a second titanium (Ti) layer in this order, for example. The thickness of the third metal film 33 is, for example, 0.1 μm or more and 10 μm or less. The third metal film 33 has a planar shape such as a rectangular shape. The range of the length of the short side and the range of the length of the long side of the third metal film 33 are the same as those of the first metal film 41 described above, for example. The planar shape of the third metal film 33 is also not limited to the rectangular shape.

The fourth metal film 61 is a metal film provided on the back surface 202 of the substrate 20 and is in contact with the back surface 202. The fourth metal film 61 may be provided only on a part of the back surface 202, or may be provided over the entire back surface 202. The fourth metal film 61 is conductive. When the semiconductor device 10 is mounted on a metal base (not shown) having a reference potential, the fourth metal film 61 is bonded to the metal base by a conductive adhesive such as silver paste. As a result, the fourth metal film 61 has the reference potential. The fourth metal film 61 is formed by stacking a nickel (Ni) layer and a gold (Au) layer in this order on the back surface 202, for example.

The second via 62 is a via that penetrates the substrate 20 and the semiconductor layer 21 to connect the first metal film 41 with the fourth metal film 61. The second via 62 is provided at a position overlapping the second metal film 31 and the third metal film 33 when viewed from the normal direction of the main surface 201. That is, the second via 62 is aligned with the MIM capacitor 70 in the normal direction of the main surface 201. The second via 62 is formed by, for example, a gold (Au) layer and a copper (Cu) layer deposited on the gold (Au) layer. The maximum diameter of the second via 62 is larger than the diameter of the first via 42 and is, for example, 100 μm. The second via 62 may have a cone shape that tapers toward the main surface 201 of the substrate 20. In this case, the maximum diameter of a portion of the second via 62 in contact with the first metal film 41 is, for example, 10 μm.

The effects of the semiconductor device 10 according to the present embodiment having the above configuration will be described. In the semiconductor device 10, the second metal film 31 that is a lower electrode of the MIM capacitor 70 is connected to the first metal film 41, which is provided above the main surface 201 of the substrate 20, by the plurality of first vias 42. In addition, the first metal film 41 is connected to the fourth metal film 61 provided on the back surface 202 of the substrate 20 by the second via 62. In this manner, the MIM capacitor 70, the plurality of first vias 42, the first metal film 41, and the second via 62 are aligned in a direction perpendicular to the main surface 201 and the back surface 202 of the substrate 20, that is, in the thickness direction of the substrate 20. Therefore, it is possible to reduce the wiring area compared to a case where a lead-out wiring (for example, a ground wiring) from one electrode of the MIM capacitor 70 is arranged in parallel with the MIM capacitor 70 as in the structure described in Japanese Unexamined Patent Publication No. 2018-37497, for example. As a result, it is possible to reduce the size of the semiconductor device 10 having the MIM capacitor 70.

In addition, in the present embodiment, instead of using the first metal film 41 as the lower electrode of the MIM capacitor 70, the second metal film 31 provided on the first insulating layer 51 is used as the lower electrode of the MIM capacitor 70. Since the flatness of the top surface of the first insulating layer 51 is improved during the process of forming the first insulating layer 51, the flatness of the top surface of the second metal film 31 provided on the first insulating layer 51 is also improved. Therefore, since the thickness of the second insulating layer 52 formed on the second metal film 31 can be made uniform, it is possible to improve the quality of the MIM capacitor 70, such as pressure resistance.

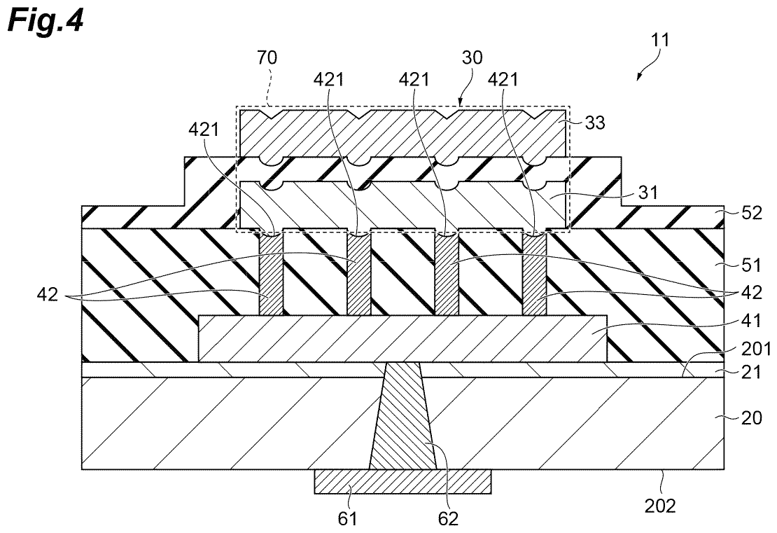

FIG. 4 is a cross-sectional view showing a semiconductor device 11 according to a modification example. The semiconductor device 11 has the same configuration as the semiconductor device 10 except for the following points. In the semiconductor device 11, each first via 42 has a slight recess 421 on its top surface. Each first via 42 is formed by forming a hole in the first insulating layer 51 and filling the hole using metal plating or metal CVD. When filling the hole in the first insulating layer 51 with a metal material, the metal material is also deposited on the inner side surfaces of the hole at the same deposition rate as on the bottom side of the hole. Therefore, since the deposition of the metal material is delayed near the center of the hole, the top surface of the first via 42 may be recessed as shown in FIG. 4. In this case, the top surface of the second metal film 31 formed on the first via 42 and the top surface of the second insulating layer 52 formed on the second metal film 31 also inherit the recess. For example, the recess of the top surface of the first via 42 may cause a recess of the top surface of the second metal film 31, and accordingly, unevenness may occur on the top surface of the second metal film 31. Even with such a semiconductor device 11, the same effects as those of the semiconductor device 10 can be achieved.

The smaller the diameter of the hole, the smaller the recess 421 formed on the top surface of the first via 42. On the other hand, if the ratio (A/B) between the inner diameter A and the depth B of the hole is too small, it is difficult for the metal material to enter the hole, and accordingly, voids are likely to form in the first via 42. In one example, the ratio (A/B) between the inner diameter A and the depth B, in other words, the ratio (D/L) between the diameter D and the length L of the first via 42 is 0.5 or more and 20 or less.

As shown in FIG. 3, the cross-sectional shape of each first via 42 may be a polygon, and each of the corners of the polygon may be larger than 90°. When the cross-sectional shape of each of the plurality of first vias 42 is a polygon, the smaller the angle of each of the plurality of corners of the polygon, the slower the deposition rate of the metal material at the plurality of corners when filling the hole in the first insulating layer 51 with the metal material. Therefore, unevenness is likely to occur on the top surface of the first via 42. Then, the unevenness of the top surface of the first via 42 is noticeable when each of the plurality of corners of the polygon is 90° or less. Therefore, if each of the plurality of corners of the polygon is set to have an angle larger than 90°, the unevenness of the top surface of the first via 42 can be kept small. That is, it is possible to improve the flatness of the top surface of the first via 42.

Keeping the unevenness of the top surface of the first via 42 small leads to keeping small the unevenness of the top surface of the second metal film 31 formed on the first via 42 and the unevenness of the top surface of the second insulating layer 52 formed on the second metal film 31. The unevenness of the top surface of the second metal film 31 and the unevenness of the top surface of the second insulating layer 52 cause a problem in the MIM capacitor 70 in that the electric field between the second metal film 31 and the third metal film 33 locally increases. By keeping the unevenness of the top surface of the first via 42 small, such a problem can be solved and a decrease in the breakdown voltage of the MIM capacitor 70 can be avoided.

As in the present embodiment, the polygon may be a regular polygon. In this case, when filling the hole in the first insulating layer 51 with a metal material, the growth rate of the metal material can be made nearly uniform along the circumferential direction of the hole. Therefore, the unevenness of the top surface of the first via 42 can be further reduced.

### MODIFICATION EXAMPLE

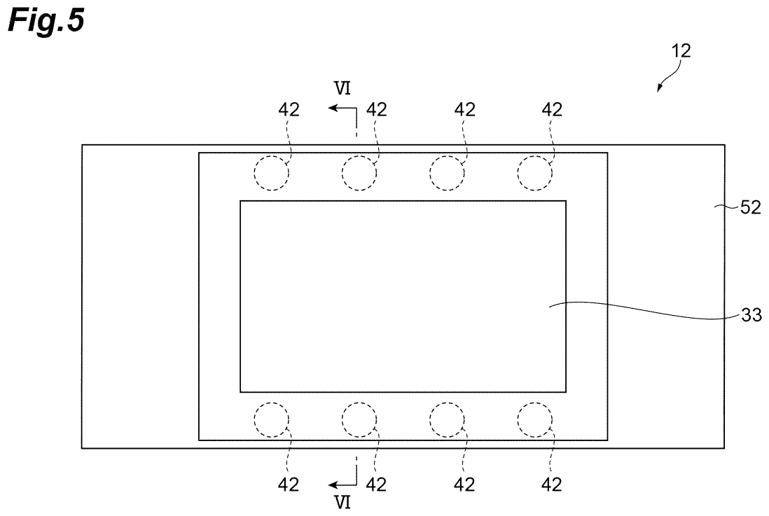

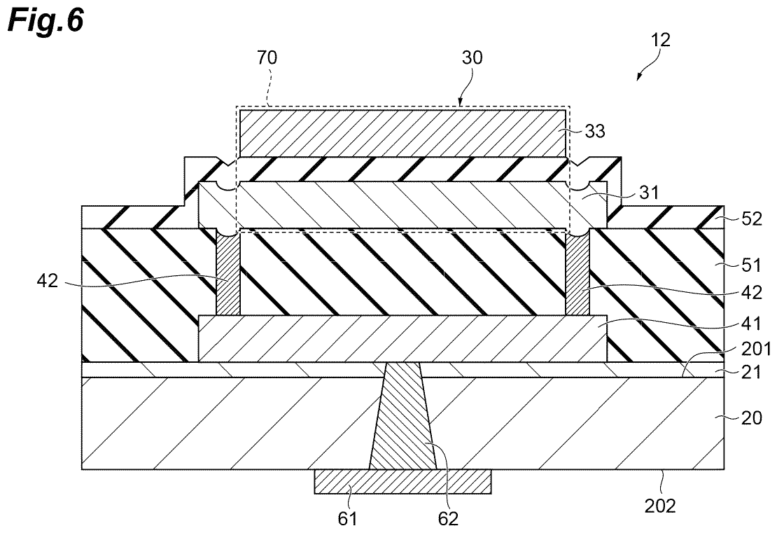

FIG. 5 is a plan view showing a semiconductor device 12 according to a modification example of the present disclosure. FIG. 6 is a cross-sectional view of the semiconductor device 12 taken along the line VI-VI shown in FIG. 5. The difference between the semiconductor device 12 and the semiconductor device 10 according to the above embodiment is a range in which the third metal film 33 is provided. That is, the third metal film 33 in this modification example is provided so as to avoid a region directly above the first via 42. In other words, the third metal film 33 in this modification example is provided in a region that does not overlap each first via 42 when viewed from the normal direction of the main surface 201. Except for this point, the configuration of the semiconductor device 12 is the same as the configuration of the semiconductor device 10.

Specifically, the planar shape of the third metal film 33 in this modification example is one size smaller than the planar shape of the second metal film 31. The third metal film 33 in this modification example is arranged between one row and the other row of the plurality of first vias 42 aligned in two rows, when viewed from the normal direction of the main surface 201. In other words, one row of the plurality of first vias 42 is aligned along one long side of the third metal film 33, and the other row of the plurality of first vias 42 is aligned along the other long side of the third metal film 33.

As described above, the top surface of each first via 42 may have unevenness. In this case, the top surface of the second metal film 31 formed on the first via 42 and the top surface of the second insulating layer 52 formed on the second metal film 31 also inherit the unevenness. When the third metal film 33 is formed on such unevenness, the uniformity of the thickness of the second insulating layer 52 in the MIM capacitor 70 may be impaired. As a result, there is a risk that the breakdown voltage of the MIM capacitor 70 may be reduced. By providing the third metal film 33 so as to avoid the region directly above each of the plurality of first vias 42 as in this modification example, a reduction in the breakdown voltage of the MIM capacitor 70 can be avoided.

The semiconductor device according to the present disclosure is not limited to the above-described embodiment, and various modifications can be made. For example, in the above embodiment, an example has been shown in which the semiconductor layer 21 is provided on the substrate 20 and the first metal film 41 is provided on the semiconductor layer 21. However, the first metal film 41 may be in contact with the substrate 20 without providing the semiconductor layer 21. Even in this case, the effects of the above embodiment can be suitably achieved.

1. A semiconductor device, comprising:
a substrate having a main surface and a back surface opposite to the main surface;
a first metal film provided above the main surface of the substrate;
a first insulating layer provided on the first metal film and in contact with the first metal film;
a second metal film provided on the first insulating layer and in contact with the first insulating layer;
a plurality of first vias penetrating the first insulating layer to connect the first metal film with the second metal film;
a second insulating layer provided on the second metal film and in contact with the second metal film;
a third metal film provided on the second insulating layer, in contact with the second insulating layer, and insulated from the second metal film by the second insulating layer;
a fourth metal film provided on the back surface of the substrate; and
a second via penetrating the substrate to connect the first metal film with the fourth metal film,
wherein the second metal film, the second insulating layer, and the third metal film form an MIM capacitor, and
the first metal film, the plurality of first vias, and the second via are aligned with the MIM capacitor in a normal direction of the main surface.

2. The semiconductor device according to claim 1,
wherein the third metal film is provided so as to avoid a region above each of the plurality of first vias.

3. The semiconductor device according to claim 1,
wherein the substrate is a silicon carbide substrate.

4. The semiconductor device according to claim 1,
wherein a cross-sectional shape of each of the plurality of first vias when each of the plurality of first vias is cut in a cross section along the main surface is a polygon, and each of a plurality of corners of the polygon is larger than 90°.

5. The semiconductor device according to claim 4,
wherein the polygon is a regular polygon.

6. The semiconductor device according to claim 1,
wherein the plurality of first vias contain at least one metal material selected from a group consisting of Au, Cu, W, Ti, Al, Ru, and Co.
